(19) United States
(12) Patent Application Publication
(10) Pub. No.: US 2026/0293059 A1
(43) Pub. Date: Sep. 24, 2026

(54) HIGHLY EFFICIENT AND ECONOMICAL SHUNT

(71) Applicant: Xiao Zeng, Zhuhai City (CN)

(72) Inventors: Xiao Zeng, Zhuhai City (CN); Yun Zeng, Zhuhai City (CN); JianFen Zhang, Zhuhai City (CN)

(21) Appl. No.: 19/178,164

(22) Filed: Apr. 14, 2025

(30) Foreign Application Priority Data
Mar. 21, 2025 (CN) 202520502847.3

(51) Int. Cl. H05K 7/20

(52) U.S. Cl. CPC H05K 7/20772

(57) ABSTRACT

A highly efficient and economical shunt comprises flat tubes and shunts, the flat tubes and shunts are combined with through brazing connection to form shunt flow channels customized according to the number of memory bank storage modules, to realize a reliable fluid circuit. Under the condition of maintaining the original narrow space, the invention fully satisfies the dual characteristics of assembly convenience and heat dissipation high efficiency, effectively eliminates the risk of interference of the liquid cooling module in the process of use, and significantly improves the protection capability of the shunt for high-power parts in the application; at the same time, it significantly optimizes the processing technology, improves its reliability, reasonableness and economy, and provides a powerful upgrade of the server heat dissipation system, which provides strong support for the upgrading of server cooling system.

### 1. TECHNICAL FIELD

The invention belongs to the technical field of heat dissipation, specifically relates to a highly efficient and economical shunt.

### 2. Background Art

With the development of technology, liquid cooling process has penetrated into the field of memory bank chip cooling. Inside the server, the restricted space requires the realization of good overall heat dissipation to meet the heat dissipation needs of high-power hardware, especially for the centralized heat dissipation of arrayed memory sticks and storage modules.

However, the existing cooling hardware configuration has obvious defects: on the one hand, it is difficult to fully adapt to the compact installation space of the server, as well as different shunt forms, and the manifold header interference problem is prominent, which seriously affects the assembly and cooling effect; on the other hand, the inadequacy of the heat dissipation flat tube structure leads to the inability to effectively guarantee the stability of heat dissipation in high-power operation. Therefore, there is an urgent need to optimize the design of the heat dissipation flat tube structure, and with the help of the innovative shunt structure, to achieve good assembly and efficient heat dissipation, to ensure stable operation of the server.

### 3. SUMMARY OF THE INVENTION

In view of the above, in order to overcome the defects of the prior art, the invention provides a highly efficient and economical shunt, which effectively solves the problems of adaptability of the existing heat dissipation fittings as well as the poor heat dissipation effect.

In order to realize the above function, the technical solution adopted in this invention is as follows: a highly efficient and economical shunt comprises flat tubes and shunts, the flat tubes and shunts are combined with through brazing connection to form shunt flow channels customized according to the number of memory bank storage modules, to realize a reliable fluid circuit, and the flat tubes are provided with clearance features, adapting to the server compact mounting space, and different shunt forms.

Preferably, the flat tubes are fabricated by processing copper tubes into flat tubes features, then performing secondary contour extrusion compression at predetermined clearance locations to integrally form a one-piece flat tube module with clearance feature; the fluid is circulated through the copper tube, to realize the overall cooling.

Preferably, the flat tubes may be structurally derived in the form of a combination of transverse or longitudinal N+1 arrangements.

Preferably, two ends of each flat tube are welded with adapter blocks, and the adapter blocks are welded to the shunts.

Preferably, the flat tube is provided with grooves at a position near both ends, the grooves being provided along an outer surface of the flat tube.

The invention adopts the above structure to achieve the following beneficial effects:
1. under the condition of maintaining the original narrow space, the invention fully satisfies the dual characteristics of assembly convenience and heat dissipation high efficiency, effectively eliminates the risk of interference of the liquid cooling module in the process of use, and significantly improves the protection capability of the shunt for high-power parts in the application; at the same time, it significantly optimizes the processing technology, improves its reliability, reasonableness and economy, and provides a powerful upgrade of the server heat dissipation system, which provides strong support for the upgrading of server cooling system
2. the production process of the invention is built on the basis of the existing conventional parts processing technology and welding process, and targeted optimization; first of all, the flat tube parts of the single structure optimization, followed by the use of brazing connection to combine various components, according to the number of memory bank storage modules, custom design shunt flow channels, so as to build up a reliable fluid circuit, with the ability to flexibly adjust its structural design according to the structure of different heat sinks, it can effectively maintain the established heat dissipation capacity regardless of the complex heat dissipation environment, and has wide applicability to meet diversified heat dissipation needs.

### 4. BRIEF DESCRIPTION OF ACCOMPANY DRAWINGS

FIG. 1 is a first overall structural diagram of a highly efficient and economical shunt provided by the invention;

FIG. 2 is a second overall structural diagram of a highly efficient and economical shunt provided by the invention;

FIG. 3 is a third overall structural diagram of a highly efficient and economical shunt provided by the invention;

FIG. 4 is a fourth overall structural diagram of a highly efficient and economical shunt provided by the invention.

As shown in the accompanying drawings:
1 flat tube, 2 shunt, 3 clearance feature, 4 adapter block, 5 groove.

### 5. SPECIFIC EMBODIMENT OF THE INVENTION

The accompanying drawings are used to provide a further understanding of the invention and form part of the specification and are used in conjunction with the embodiments of the invention for the purpose of explaining the invention and do not constitute a limitation of the invention.

In the description of the embodiments of the invention, it should be noted that, if the terms “center”, “up”, “down”, “left”, “right”, “vertical”, “horizontal”, “inner”, “outer”, etc. indicate orientations or positional relationships based on the orientations or positional relationships shown in the drawings or the orientations or positional relationships that the products of the invention are usually placed in when used, the orientations or positional relationships are only used for convenience of describing the invention and simplifying the description, but the terms do not indicate or imply that the devices or elements indicated must have specific orientations, be constructed in specific orientations, and operate, and therefore, should not be construed as limiting the invention. Furthermore, the terms “first”, “second”, “third” and the like are used solely to distinguish one from another and are not to be construed as indicating or implying relative importance.

The invention is further described in detail hereinafter with reference to the drawings.

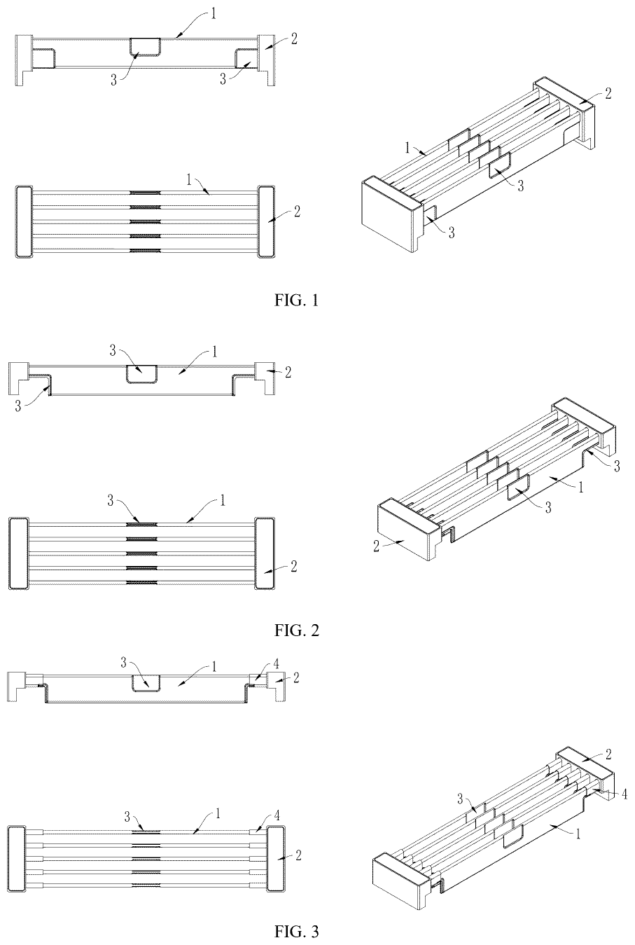

As shown from FIG. 1 to FIG. 4, a highly efficient and economical shunt comprises flat tubes 1 and shunts 2, the flat tubes 1 and shunts 2 are combined with through brazing connection to form shunt flow channels customized according to the number of memory bank storage modules, to realize a reliable fluid circuit; the flat tubes 1 may be structurally derived in the form of a combination of transverse or longitudinal N+1 arrangements, to realize the purpose of full-scene installation; the flat tubes 1 are provided with clearance features 3, adapting to the server compact mounting space, and different shunt 2 forms.

Wherein, the flat tubes 1 are fabricated by processing copper tubes into flat tubes 1 features, then performing secondary contour extrusion compression at predetermined clearance locations to integrally form a one-piece flat tube 1 module with clearance feature; the fluid is circulated through the copper tube, to realize the overall cooling.

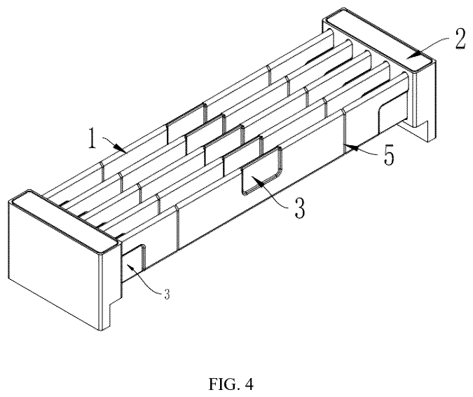

As shown in FIG. 3, two ends of each flat tube 1 are welded with adapter blocks 4, and the adapter blocks 4 are welded to the shunts 2.

As shown in FIG. 4, the flat tube 1 is provided with grooves 5 at a position near both ends, the grooves 5 being provided along an outer surface of the flat tube 1, which can change the stress distribution of the flat tube 1 to a certain extent, and when the flat tube 1 is subjected to external forces, such as pressure, tension, or vibration, the grooves 5 can be used as a buffer region for stress concentration, so that the stress is dispersed at the grooves 5, avoiding excessive concentration of the stress in certain specific parts of the flat tube, thereby reducing the risk of rupture or deformation of the flat tubes 1, and improving the overall structural stability and reliability of the flat tubes 1. In addition, a sealing washer, snap or bolt and other connectors can be embedded in the groove 5, so that the flat tube 1 can be connected to other heat dissipation structures, which can be used to rapidly emit heat.

For specific use, the flat tubes 1 are welded to the shunts 2 to ensure a firm connection and good sealing, forming a one-piece heat dissipation module, so that the coolant can circulate in the flat tubes 1 to form a circulating loop to realize overall heat dissipation;

The number of flat tubes 1 is customized according to the number of memory bank storage modules, and the flat tubes 1 monolithic body can be applied with different combinations of forms, lengths, widths, and thicknesses of dimensions that can be designed and applied according to the actual use. Determine the appropriate shunts 2 structure, set up different collocation methods, such as N+1 horizontal connection method with the derived structure, or multiple heat source arrangement, longitudinal N+1 alignment and other combination forms, to meet the adaptability of a full-scene heat dissipation design structure.

The invention and its embodiments have been described above, but the description is not limited thereto; only one embodiment of the invention is shown in the drawings, and the actual structure is not limited thereto. In general, it is to be understood by those skilled in the art that non-creative design of structural forms and embodiments that are similar to the technical solutions without departing from the spirit of the invention shall all fall within the protective scope of the invention.

1. A highly efficient and economical shunt, comprising flat tubes and shunts, the flat tubes and shunts are combined with through brazing connection to form shunt flow channels customized according to the number of memory bank storage modules, to realize a reliable fluid circuit, and the flat tubes are provided with clearance features.

2. The highly efficient and economical shunt of claim 1, wherein the flat tubes are fabricated by processing copper tubes into flat tubes features, then performing secondary contour extrusion compression at predetermined clearance locations to integrally form a one-piece flat tube module with clearance feature.

3. The highly efficient and economical shunt of claim 2, wherein the flat tubes may be structurally derived in the form of a combination of transverse or longitudinal N+1 arrangements.

4. The highly efficient and economical shunt of claim 3, wherein two ends of each flat tube are welded with adapter blocks, and the adapter blocks are welded to the shunts.

5. The highly efficient and economical shunt of claim 1, wherein the flat tube is provided with grooves at a position near both ends, the grooves being provided along an outer surface of the flat tube.
